(19) United States
(12) Patent Application Publication
(10) Pub. No.: US 2024/0162121 A1
(43) Pub. Date: May 16, 2024

(54) INTEGRATED CIRCUIT PACKAGE WITH WIRE BOND

(71) Applicant: TEXAS INSTRUMENTS INCORPORATED, Dallas, TX (US)

(72) Inventors: STANLEY CHOU, NEW TAIPEI CITY (TW); HSIANG MING HSIAO, TAIPEI (TW)

(21) Appl. No.: 17/988,115

(22) Filed: Nov. 16, 2022

(51) Int. Cl. H01L 23/495; H01L 21/56; H01L 23/00; H01L 23/31

(52) U.S. Cl. CPC H01L 23/49541; H01L 21/561; H01L 23/3107; H01L 24/48; H01L 24/85; H01L 2224/48151; H01L 2224/85

(57) ABSTRACT

An integrated circuit (IC) package includes an interconnect. The interconnect has a connecting tie bar and a die pad. The IC package also includes a die mounted on the die pad of the interconnect. The IC package further includes a wire bond coupled to the die and the connecting tie bar to provide a current path between the die and the connecting tie bar.

### TECHNICAL FIELD

This disclosure relates to an integrated circuit (IC) package with a wire bond.

### BACKGROUND

An interconnect (alternatively referred to as a lead frame) is a metal structure inside an integrated circuit (IC) package that carries signals from a die to the outside. The interconnect includes a die pad, where the die is placed, surrounded by leads, metal conductors leading away from the die to the external circuits. The end of each lead closest to the die ends in a bond pad. Small wire bonds connect the die to each bond pad. Mechanical connections fix these parts into a rigid structure, which makes the whole interconnect easy to handle automatically.

The die is glued or soldered to the die pad inside the interconnect, and then wire bonds are attached between the die and the bond pads to connect the die to the leads. In a process called encapsulation, a plastic case is molded around the lead frame and die, exposing only the leads. The leads are cut off outside the plastic body and exposed supporting structures are cut away. The external leads are then bent (formed) to the desired shape. In various examples, interconnects are employed to manufacture a quad flat no-leads package (QFN), a quad flat package (QFP), or a dual in-line package (DIP).

### SUMMARY

A first example relates to an integrated circuit (IC) package that includes an interconnect. The interconnect has a connecting tie bar and a die pad. The IC package also includes a die mounted on the die pad of the interconnect. The IC package further includes a wire bond coupled to the die and the connecting tie bar to provide a current path between the die and connecting the tie bar.

A second example relates to a strip of IC packages that includes a strip of interconnects. The strip of interconnects includes connecting tie bars and die pads. The strip of IC packages also includes dies mounted on the die pads of the strip of interconnects. The strip of IC packages has wire bonds coupled to the dies and the connecting tie bars to provide a current path between the dies and the tie bars.

A third example relates to a method for forming IC packages. The method includes mounting dies on die pads of a strip of interconnects. The strip of interconnects include the die pads and connecting tie bars. The method also includes applying wire bonds between the dies and the connecting tie bars of the strip of interconnects and flowing a mold compound on the strip of interconnects to form a strip of IC packages.

### BRIEF DESCRIPTION OF THE DRAWINGS

FIG. 1 illustrates an example integrated circuit (IC) package with a wire bond coupling a die and a connecting tie bar.

FIG. 2 illustrates another example IC package with multiple wire bonds coupling a die and connecting tie bars.

FIG. 3 illustrates another example IC package with a wire bond coupling a die and a connecting tie bar.

FIG. 4 illustrates another example IC package encapsulated in a molding compound.

FIG. 5 illustrates a strip of IC packages with wire bonds coupling dies and connecting tie bars.

FIG. 6 illustrates a first stage of an example method for forming IC packages that have a wire bond coupling a die and a connecting tie bar.

FIG. 7 illustrates a second stage of the example method for forming IC packages that have a wire bond coupling a die and a connecting tie bar.

FIG. 8 illustrates a third stage of the example method for forming IC packages that have a wire bond coupling a die and a connecting tie bar.

FIG. 9 illustrates a fourth stage of the example method for forming IC packages that have a wire bond coupling a die and a connecting tie bar.

FIG. 10 illustrates a flowchart of an example method for forming IC packages that have a wire bond coupling a die and a connecting tie bar.

### DETAILED DESCRIPTION

This description relates to an integrated circuit (IC) package. The IC package has an interconnect (e.g., a lead frame). The interconnect includes a connecting tie bar and a die pad. A die is mounted on the die pad of the interconnect. A wire bond is coupled to the die and the connecting tie bar to provide a current path between the die and the connecting tie bar.

The die pad includes epoxy bleed out along a periphery of the die that is formed when the die is mounted on the die pad. Inclusion of the wire bond avoids the need to couple the die to the die pad, such that the wire bond avoids contact with the epoxy bleed out. This architecture enables the die to be sized to leverage a larger portion of the die pad than other approaches. More specifically, edges of the die are separated from edges of the die pad by a distance of about 200 micrometers (μm) or more without increasing a likelihood of failure of the IC package. Stated differently, the wire bond enables a current path between the connecting tie bar and the die. This current path avoids the need for a wire bond between the die and the die pad that would be prone to failure.

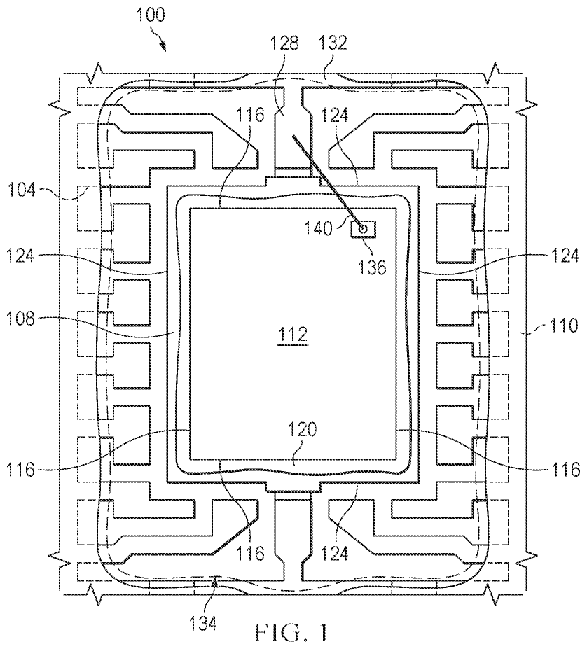

FIG. 1 illustrates an example IC package 100. In various examples, the IC package 100 is a quad flat no lead (QFN) package, a dual flat no lead (DFN) package, etc. The IC package 100 includes an interconnect 104. The interconnect 104, alternatively referred to as a lead frame, includes a die pad 108 situated in a central region of the interconnect 104. The die pad 108 is alternatively referred to as a die attach pad. A die 112 is mounted on the die pad 108. An epoxy is employed to attach the die 112 to the die pad 108. A mold compound 110 encapsulates the die 112 and the interconnect 104.

In some examples, the IC package 100 has been singulated from a strip of IC packages. In such an example, the interconnect 104 is formed from a strip of interconnects, such as a strip of interdigitated high density (HYDE) interconnects.

To mount the die 112 on the die pad 108 the epoxy is applied on the interconnect 104, including the die pad 108. The die 112 is placed on the epoxy covered die pad 108. A clamp is applied to the die 112 and the interconnect 104 to reduce a gap between the die 112 and the die pad 108. Accordingly, the epoxy squeezes out from the edges 116 (a periphery) of the die pad 108. This squeeze out is referred to as epoxy bleed out 120 that is formed between the edges 116 of the die 112 and edges 124 (a periphery) of the die pad 108. The epoxy bleed out 120 is represented with an amorphous shape that extends beyond the edges 116 of the die 112. To curtail the likelihood that the epoxy bleed out 120 extends to the edges 124 of the die pad 108, the die 112 is sized such that there is at least about a 200 micrometer (μm) distance between the edges 116 of the die 112 and the edges 124 of the die pad 108. Unless otherwise stated, in this description, ‘about’ preceding a value means+/−10 percent of the stated value.

The interconnect 104 includes a connecting tie bar 128 that extends from the die pad 108 to a connecting bar 132 at a periphery of the IC package 100. In some examples, a current path extends between the die pad 108 and the connecting tie bar 128. In other examples, the connecting tie bar 128 and the die pad 108 are galvanically isolated. In some examples, the connecting bar 132 is configured to be coupled to an external node. Accordingly, in these examples, the connecting tie bar 128 (coupled to the connecting bar 132) operates as a neutral (e.g., ground) node for the IC package 100. In other examples, the connecting bar 132 is removed during a singulation operation.

In the example illustrated, the clamp employed to apply pressure to mount the die 112 overlays a region 134 indicated by a dashed line. The region 134 includes the die 112 and the connecting tie bar 128. By applying force in the region 134, failure of the wire bond 140 is curtailed.

The die 112 includes an embedded circuit. A node 136 on the die 112 is configured to be coupled to the connecting bar 132. In some examples, the node 136 represents an electrically neutral node for the die 112. To couple the node 136 to the connecting bar 132, a wire bond 140 is attached to the node 136 and to the connecting tie bar 128. This wire bond 140 provides an electrical connection between the node 136 and the connecting tie bar 128. The wire bond 140 avoids contact with the die pad 108. Thus, the wire bond 140 provides a current path between the node 136 and the connecting tie bar 128, such that the die 112 is coupled to the connecting bar 132, which is an electrically neutral node in some examples.

Inclusion of the wire bond 140 avoids the need to have a wire bond coupled to the die pad 108. Instead, the node 136 of the die 112 is coupled to the connecting bar 132 through the wire bond 140 and the connecting tie bar 128. In this manner, contact with the epoxy bleed out 120 is avoided, thereby curtailing failure of the IC package 100. Moreover, the die 112 can be sized to take advantage of the available real estate on the die pad 108 without needing to include room for a wire bond on the die pad 108 itself.

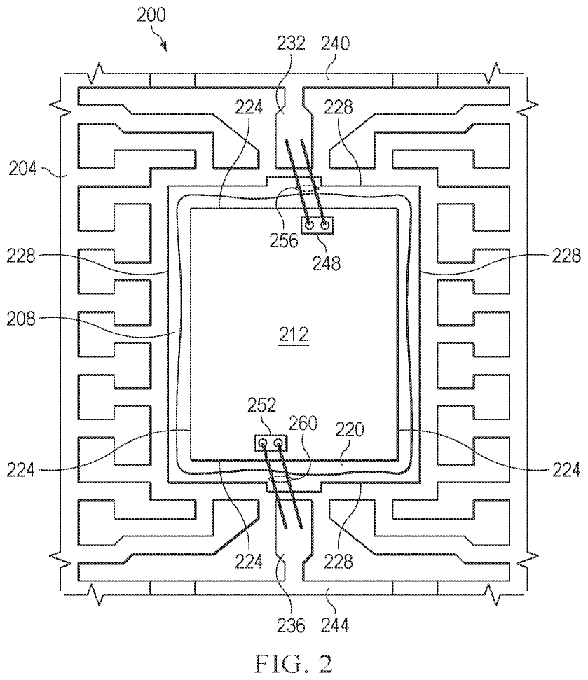

FIG. 2 illustrates another example of an IC package 200. The IC package 200 includes an interconnect 204. The interconnect 204 is employable to implement the interconnect 104 of FIG. 1. A die 212 is mounted on the die pad 208. An epoxy is employed to attach the die 212 to the die pad 208. A mold compound (hidden from view) encapsulates the die 212 and the interconnect 204.

Mounting the die 212 forms epoxy bleed out 220 between edges 224 (a periphery) of the die 212 and edges 228 (a periphery) of the die pad 208. To curtail the likelihood that the epoxy bleed out 220 extends to the edges 228 of the die pad 208, the die 212 is sized such that there is at least about a 200 micrometer (μm) distance between the edges 224 of the die 212 and the edges 228 of the die pad 208.

The interconnect 204 includes a first connecting tie bar 232 and a second connecting tie bar 236 that extends from opposing regions near the die pad 208 to a first connecting bar 240 and a second connecting bar 244 at a periphery of the IC package 200. In the illustrated example, the first connecting tie bar 232 and the second connecting tie bar 236 are galvanically isolated from the die pad 208. Additionally, in some examples, the first connecting bar 240 and the second connecting bar 244 are electrically coupled, such that the first connecting tie bar 232 and the second connecting tie bar 236 are also electrically coupled. The first connecting bar 240 and the second connecting bar 244 are configured to be coupled to an external node, such as an electrically neutral node. Accordingly, in these examples, the first connecting tie bar 232 and the second connecting tie bar 236 (coupled to the first connecting bar 240 and the second connecting bar 244) operates as a neutral (e.g., ground) node for the IC package 200.

The die 212 includes an embedded circuit. A first node 248 on the die 212 is configured to be coupled to the first connecting bar 240 and a second node 252 on the die 212 is configured to be coupled to the second connecting bar 244. In some examples, the first node 248 and the second node 252 represent an electrically neutral node for the die 212. To couple the first node 248 to the first connecting tie bar 232, a first set of wire bonds 256 are attached to the first node 248 and to the first connecting tie bar 232. Additionally, to couple the second node 252 to the second connecting bar 244, a second set of wire bonds 260 are attached to the second node 252 of the die 212. In the example illustrated, there are two wire bonds coupling the die 212 to the first connecting tie bar 232 and two wire bonds coupling the die 212 to the second connecting tie bar 236. In other examples, there could be more or less wire bonds. The first set of wire bonds 256 provides a current path between the first node 248, the first connecting tie bar 232 and the first connecting bar 240. The second set of wire bonds 260 provides a current path between the second node 252, the second connecting tie bar 236 and the second connecting bar 244. Thus, in some examples, the first set of wire bonds 256 and the second set of wire bonds 260 couple the first node 248 and the second node 252 to an electrically neutral node. Also, the wire bonds in the first set of wire bonds 256 and the second set of wire bonds 260 avoid contact with the die pad 208. Moreover, inclusion of multiple wire bonds to couple the first node 248 and the second node 252 to the first connecting bar 240 and the second connecting bar 244, respectively, allows the IC package 200 to support a greater current than the IC package 100 of FIG. 1.

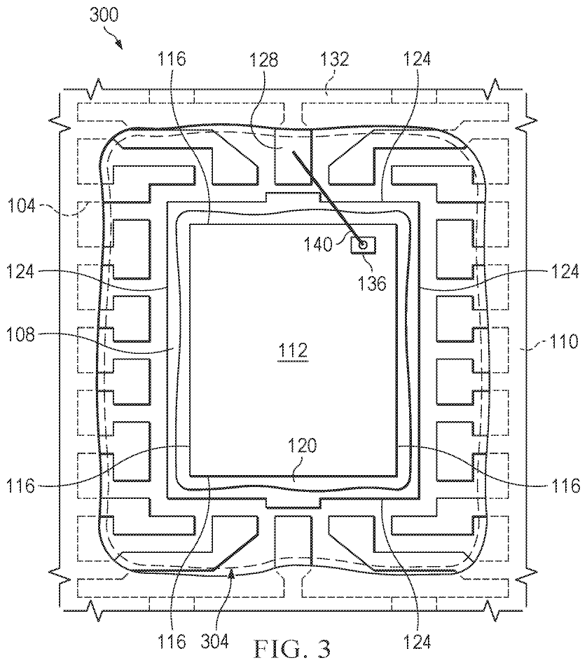

FIG. 3 illustrates an example IC package 300. The IC package 300 is similar to the IC package 100 of FIG. 1. Thus, the IC package 300 and the IC package 100 of FIG. 1 employ the same reference numbers to denote the same structures. Moreover, some reference numbers are not reintroduced for simplicity.

In the example illustrated, a clamp employed to apply pressure to mount the die 112 on the die pad 108 covers a region 304 indicated by a dashed box. The region 304 overlays the die 112 and the die pad 108. However, the region 304 does not include the connecting bar 132 or a portion of the connecting tie bar 128 in contrast to the region 134 of FIG. 1. In comparison to the IC package 100 of FIG. 1, in the IC package 300, the die 112 is attached with a conventional clamp.

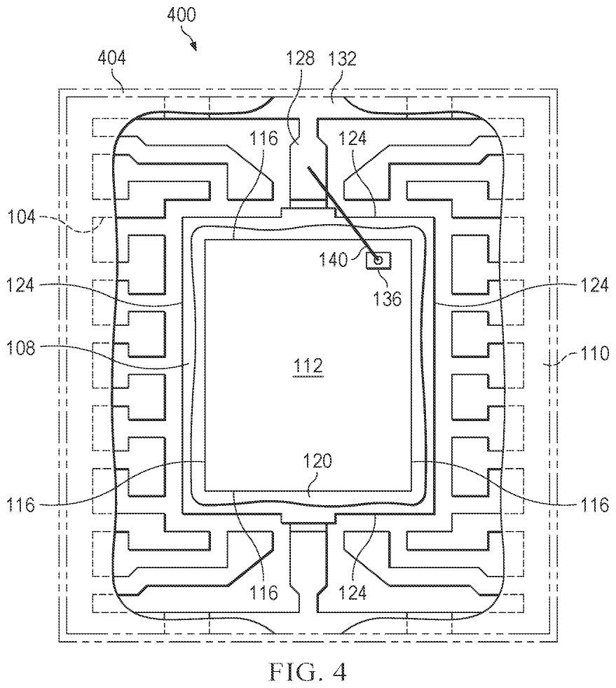

FIG. 4 illustrates an example IC package 400. The IC package 400 is similar to the IC package 100 of FIG. 1. Thus, the IC package 400 and the IC package 100 of FIG. 1 employ the same reference numbers to denote the same structures. Moreover, some reference numbers are not reintroduced for simplicity.

The IC package 400 includes a periphery of a mold compound 404. The mold compound 404 is formed of the same material as other portions of the mold compound 110. The mold compound 404 and the mold compound 110 encapsulates the die 112, the interconnect 104 and the wire bond 140. The mold compound 404 and the mold compound 110 are formed of a non-conductive polymer, such as plastic.

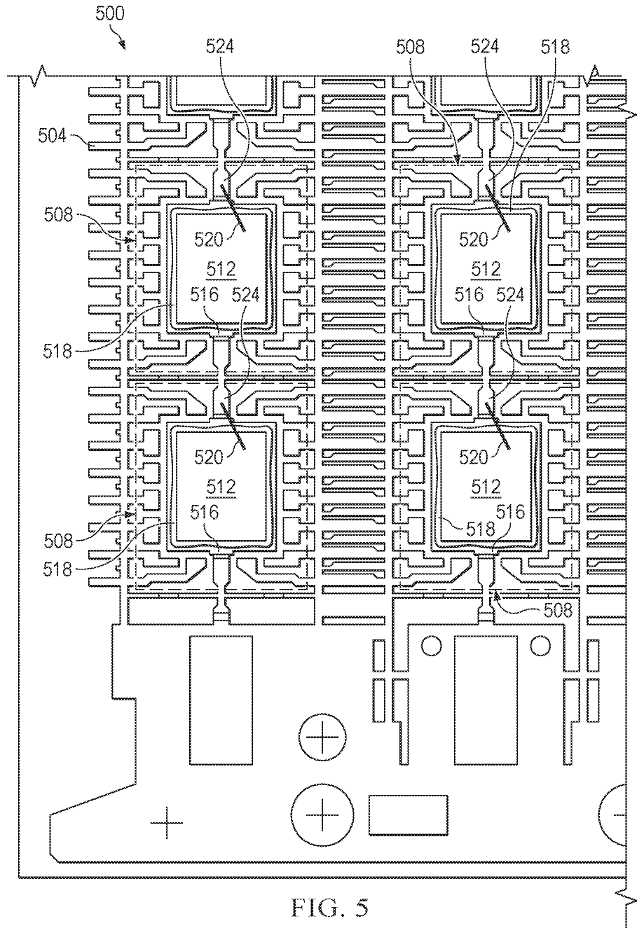

FIG. 5 illustrates an example of a strip of IC packages 500. The strip of IC packages 500 includes a strip of interconnects 504, such as an interdigitated HYDE interconnect. The IC packages 500 includes a strip of IC packages 508 prior to singulation. The IC packages 508 of the strip of IC packages 500 are singulatable around the boundaries of the IC packages 508 indicated with dashed lines. In the illustrated example, there are four (4) IC packages 508. In other examples, there are more or less IC packages 508. The IC packages 508 represent an example of the IC package 100 of FIG. 1. The IC packages 508 include a die 512 mounted on a die pad 516 of the strip of interconnects 504. Attaching the dies 512 to the die pads 516 causes an epoxy bleed out 518. The IC packages 508 include a wire bond 520 that couples a node of the corresponding die 512 to a connecting tie bar 524 of the interconnect 504. The wire bonds 520 avoid the need to have the dies 512 galvanically coupled to the die pads 516. Accordingly, the likelihood of failure of the IC packages is curtailed.

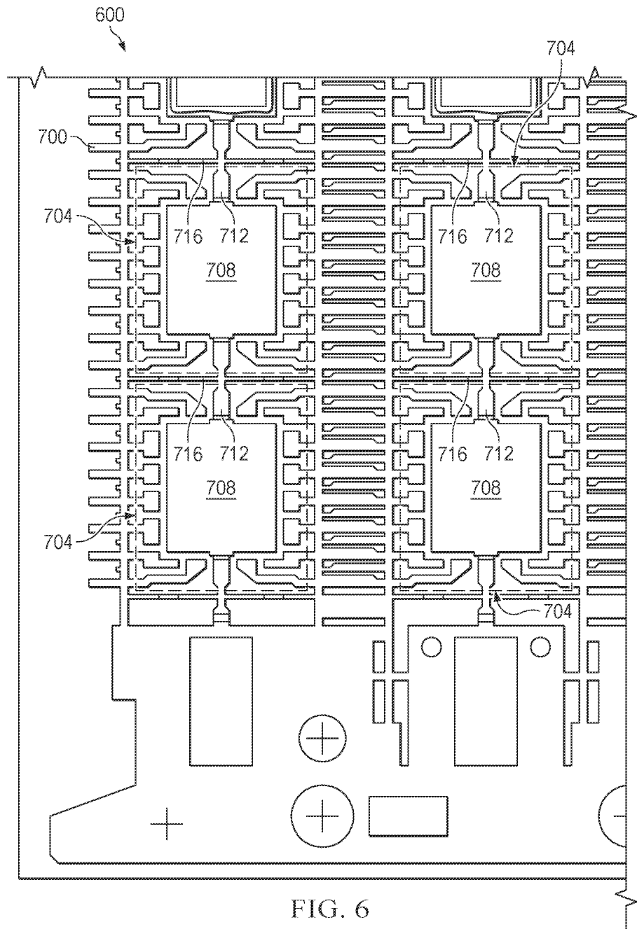

FIGS. 6-9 illustrate stages of a method for forming IC packages. For purposes of simplification of explanation, FIGS. 6-9 employ the same reference numbers to denote the same structure.

At 600, in a first stage, as illustrated in FIG. 6, a strip of interconnects 700 is provided. The strip of interconnects 700 is employable to implement the strip of individual interconnects 504 illustrated in FIG. 5, prior to singulation. The strip of interconnects 704 prior to singulation is an interdigitated HYDE strip of interconnects, alternatively referred to as an interdigitated HYDE lead frame. The strip of interconnects 700 includes interconnects 704 that are singulatable along illustrated dashed lines at the periphery of the interconnects 704. In the example illustrated, there are four (4) interconnects 704, but in other examples, there are more or less interconnects 704. The interconnects 704 include die pads 708 for mounting dies thereon.

The interconnects 704 also include a connecting tie bar 712 that is connected to a connecting bar 716. In some examples, the connecting bar 716 is used as a saw street that is removed during singulation. In other examples, the connecting bar 716 is a lead, such as a lead configured to be coupled to an external node.

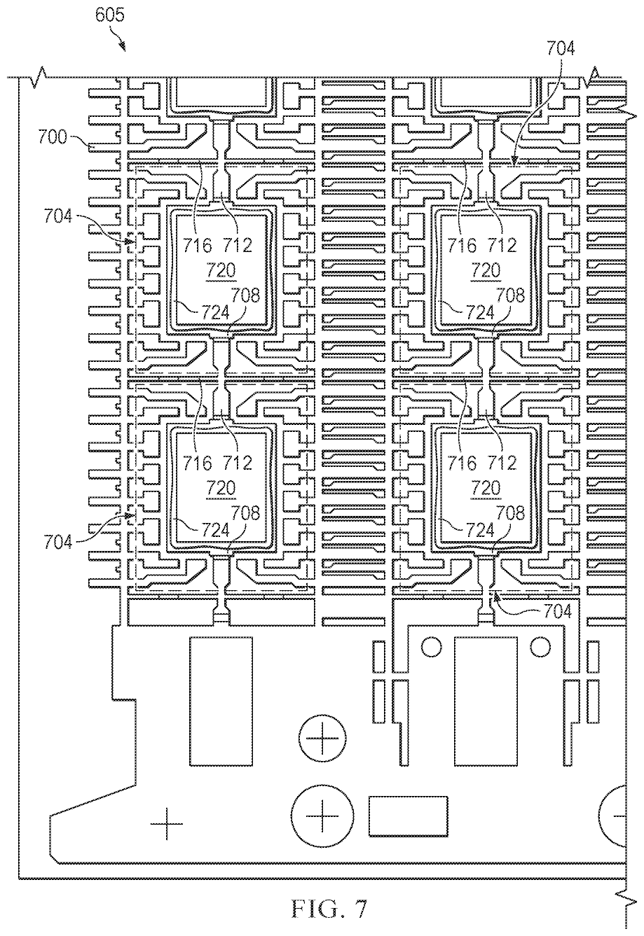

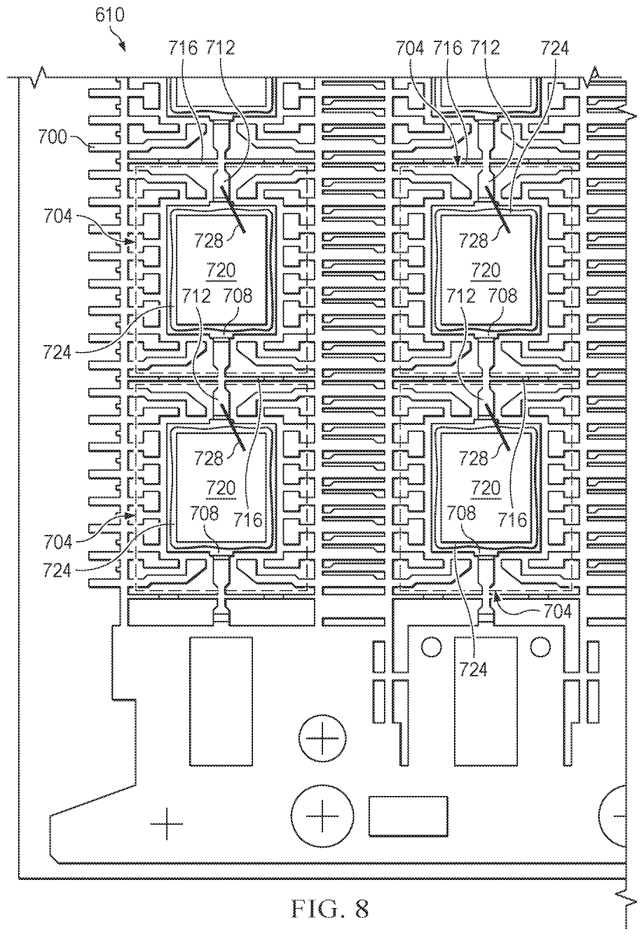

At 605, in a second stage, as illustrated in FIG. 7, dies 720 are mounted on the die pads 708. The dies 720 are mounted with epoxy, which causes epoxy bleed out 724. At 610, in a third stage, as illustrated in FIG. 8, wire bonds 728 are coupled to the dies 720 and to the connecting tie bars 712. The wire bonds 728 provide a current path between the connecting tie bars 712 and the dies 720. Inclusion of the wire bonds 728 avoids the need to provide a current path between the dies 720 and the die pads 708. Additionally, in the third stage, a mold compound is applied in an encapsulation operation. The mold compound encapsulates the interconnects 704, the dies 720 and the wire bonds 728, forming a strip of IC packages.

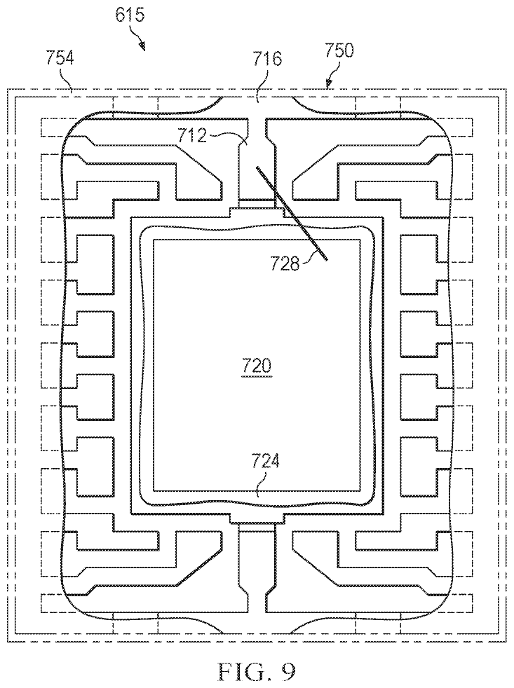

At 615, in a fourth stage, as illustrated in FIG. 9, the IC packages are singulated, forming an IC package 750, which can be referred to as a given IC package. The IC package 750 is employable to implement the IC package 400 of FIG. 4. The IC package 750 includes a mold compound 754, one of the dies 720 and one of the wire bonds 728. The wire bond 728 avoids contact with the epoxy bleed out 724 to curtail a likelihood of failure of the IC package 750.

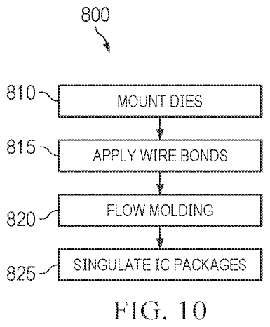

FIG. 10 is a flowchart of an example method 800 for forming IC packages, such as the IC package 100 of FIG. 1. At 810, dies (e.g., the dies 720 of FIG. 8) are mounted on die pads of a strip of interconnects (e.g., the strip of interconnects 700 of FIG. 7). The strip of interconnects includes the die pads (e.g., the die pads 708 of FIG. 7) and connecting tie bars (e.g., the connecting tie bars 712 of FIG. 7). In some examples, the die pads of the strip of interconnects are galvanically isolated from the connecting tie bars.

At 815, wire bonds are applied between the dies and the connecting tie bars of the strip of interconnects. At 820, a mold compound is flowed on the strip of interconnects to form a strip of IC packages (e.g., the strip of IC packages 500 of FIG. 5). At 825, the IC packages are singulated from the strip of IC package to form IC packages (e.g., instance of the IC package 500 of FIG. 5).

Modifications are possible in the described embodiments, and other embodiments are possible, within the scope of the claims.

What is claimed is:

1. An integrated circuit (IC) package comprising:
an interconnect comprises:
a connecting tie bar;
a die pad;
a die mounted on the die pad of the interconnect; and
a wire bond coupled to the die and the connecting tie bar to provide a current path between the die and the connecting tie bar.

2. The IC package of claim 1, wherein the connecting tie bar is galvanically isolated from the die pad.

3. The IC package of claim 1, wherein the wire bond is a first wire bond, the IC package further comprising a second wire bond coupled to the die and to the tie bar of the interconnect.

4. The IC package of claim 1, wherein an edge of the die and an edge of the die pad are separated by about 200 micrometers (μm) or more.

5. The IC package of claim 1, wherein the tie bars are coupled to an electrically neutral node.

6. The IC package of claim 1, further comprising a mold compound encapsulating the die and a portion of the interconnect.

7. A strip of integrated circuit (IC) packages comprising:
a strip of interconnects comprising:
connecting tie bars;
die pads;
dies mounted on the die pads of the strip of interconnects; and
wire bonds coupled to the dies and the connecting tie bars to provide a current path between the dies and the tie bars.

8. The strip of IC packages of claim 7, wherein the connecting tie bars are galvanically isolated from the die pads.

9. The strip of IC packages of claim 7, wherein a given IC package of the strip of IC packages includes two or more wire bonds that couple a respective die of the IC package to a respective connecting tie bar of the strip of interconnects.

10. The strip of IC packages of claim 7, wherein a given IC package of the strip of IC packages has a distance between an edge of a respective die pad and an edge of a respective die of about 200 micrometers (μm) or more.

11. The strip of IC packages of claim 7, wherein the tie bars are coupled to an electrically neutral node.

12. A method for forming integrated circuit (IC) packages comprising:
mounting dies on die pads of a strip of interconnects, wherein the strip of interconnects comprises:
the die pads;
connecting tie bars;
applying wire bonds between the dies and the connecting tie bars of the strip of interconnects; and
flowing a mold compound on the strip of interconnects to form a strip of IC packages.

13. The method of claim 12, further comprising singulating the strip of IC packages to form IC packages.

14. The method of claim 12, wherein the die pads of the strip of interconnects are galvanically isolated from the connecting tie bars.

15. The method of claim 12, wherein a given IC package of the strip of IC packages includes two or more wire bonds that couple a respective die of the IC package to a respective connecting tie bar of the strip of interconnects.

16. The method of claim 12, wherein a given IC package of the strip of IC packages has a distance between an edge of a respective die pad and an edge of a respective die of about 200 micrometers (μm) or more.

17. The method of claim 12, wherein the tie bars are coupled to an electrically neutral node.
